(19) United States
(12) Patent Application Publication
(10) Pub. No.: US 2024/0321724 A1
(43) Pub. Date: Sep. 26, 2024

(54) METAL-INSULATOR-METAL (MIM) CAPACITOR INTERCONNECT FOR HIGH-QUALITY (Q) INDUCTOR-CAPACITOR (LC) FILTER

(71) Applicant: QUALCOMM Incorporated, San Diego, CA (US)

(72) Inventors: Doosoub SHIN, Incheon (KR); Changhan Hobie YUN, San Diego, CA (US); Youngju PARK, Incheon (KR)

(21) Appl. No.: 18/188,965

(22) Filed: Mar. 23, 2023

(51) Int. Cl. H01L 23/522; H01L 23/48; H01L 23/498

(52) U.S. Cl. CPC H01L 23/5223; H01L 23/481; H01L 23/49816; H01L 23/49827; H01L 23/5227; H01L 2223/6616; H01L 2223/6661

(57) ABSTRACT

A device includes a passive substrate having a first metallization layer on a first surface of the passive substrate. The first metallization layer is composed of a first passive component and a first plate portion. The device includes an insulator layer coupled to the first plate portion of the first metallization layer. The device also includes a first conductive interconnect coupled to the insulator layer to form a second passive component coupled to the first passive component. The device further includes a laminate substrate coupled to the first conductive interconnect.

### BACKGROUND

### Field

Aspects of the present disclosure relate to semiconductor devices and, more particularly, to a metal-insulator-metal (MIM) capacitor interconnect for a high-quality (Q) inductor/capacitor (LC) filter.

### Background

Wireless communications devices incorporate radio frequency (RF) modules that facilitate the communication and features users expect. As wireless systems become more prevalent and include more capabilities, the chips become more complex. Fifth generation (5G) new radio (NR) and sixth generation (6G) wireless communications devices incorporate the latest generation of electronic dies that are packed into smaller modules with smaller interconnections. Design challenges include integrating passive devices and active devices to implement RF front-end (RFFE) modules.

An RFFE module may be implemented by integrating RF filters, active devices, and surface-mount technology (SMT) devices on a laminate substrate. These RF filters, active devices, and SMT devices are conventionally arranged in a side-by-side on package configuration supported by a laminate substrate. Unfortunately, these conventional side-by-side on package laminate configurations are subjected to decreasing XY size and Z height limitations due to the reduced form factor of future applications. That is, the XY size and Z height dimensions of conventional side-by-side on package laminate configurations exceed the form factor of future RFFE module applications. An RFFE implementation that meets reduced XY size and Z height dimensions specified by the form factor of future RFFE module applications is desired.

### SUMMARY

A device includes a passive substrate having a first metallization layer on a first surface of the passive substrate. The first metallization layer is composed of a first passive component and a first plate portion. The device includes an insulator layer coupled to the first plate portion of the first metallization layer. The device also includes a first conductive interconnect coupled to the insulator layer to form a second passive component coupled to the first passive component. The device further includes a laminate substrate coupled to the first conductive interconnect.

A method for fabricating a radio frequency (RF) device is described. The method includes plating a first metallization layer on a first surface of a passive substrate, the first metallization layer comprising a first passive component and a first plate portion. The method also includes depositing an insulator layer on the first plate portion of the first metallization layer. The method further includes forming a first conductive interconnect coupled to the insulator layer to form a second passive component coupled to the first passive component. The method also includes coupling a laminate substrate to the first conductive interconnect.

This has outlined, rather broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for carrying out the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 is a schematic diagram of a radio frequency front-end (RFFE) module employing active and passive devices.

FIG. 2 is a schematic diagram of a radio frequency integrated circuit (RFIC) chip having a wireless local area network (WLAN) module and a radio frequency front-end (RFFE) module for a chipset.

FIG. 3 is a block diagram illustrating a cross-sectional view of a radio frequency front-end (RFFE) module including a semiconductor die and an integrated passive device (IPD) filter die, in accordance with aspects of the present disclosure.

FIGS. 4A and 4B are block diagrams illustrating a radio frequency (RF) device including metal-insulator-metal (MIM) capacitor interconnects for high-quality (Q) inductor-capacitor (LC) filters, according to aspects of the present disclosure.

FIG. 5 is a block diagram illustrating a radio frequency (RF) device including a metal-insulator-metal (MIM) capacitor interconnect for a high-quality (Q) inductor-capacitor (LC) filter, according to aspects of the present disclosure.

FIG. 6 is a block diagram further illustrating the radio frequency (RF) device including a metal-insulator-metal (MIM) capacitor interconnect for a high-quality (Q) inductor-capacitor (LC) filter, according to further aspects of the present disclosure.

FIGS. 7A and 7B are block diagrams further illustrating the radio frequency (RF) devices of FIGS. 4A and 4B, according to aspects of the present disclosure.

FIGS. 8A-8E are block diagrams illustrating a process of fabricating the radio frequency (RF) device of FIG. 4B, including a metal-insulator-metal (MIM) capacitor interconnect for a high-quality (Q) inductor-capacitor (LC) filter, according to aspects of the present disclosure.

FIGS. 9A-9F are block diagrams illustrating a process of fabricating the radio frequency (RF) device of FIG. 5, including a metal-insulator-metal (MIM) capacitor interconnect for a high-quality (Q) inductor-capacitor (LC) filter, according to aspects of the present disclosure.

FIG. 10 is a process flow diagram illustrating a method for fabricating a radio frequency (RF) device, including a metal-insulator-metal (MIM) capacitor interconnect for a high-quality (Q) inductor-capacitor (LC) filter, according to aspects of the present disclosure.

FIG. 11 is a block diagram showing an exemplary wireless communications system in which a configuration of the present disclosure may be advantageously employed.

FIG. 12 is a block diagram illustrating a design workstation used for circuit, layout, and logic design of a semiconductor component according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described herein, the use of the term “and/or” is intended to represent an “inclusive OR,” and the use of the term “or” is intended to represent an “exclusive OR.” As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described herein, the term “proximate” used throughout this description means “adjacent, very near, next to, or close to.” As described herein, the term “on” used throughout this description means “directly on” in some configurations, and “indirectly on” in other configurations.

Wireless communications devices incorporate radio frequency (RF) modules that facilitate the communication and features users expect. As wireless systems become more prevalent and include more capabilities, the chips become more complex. For example, mobile RF chips (e.g., mobile RF transceivers) have migrated to a deep sub-micron process node due to cost and power consumption considerations. Designing mobile RF transceivers is complicated by added circuit functions for supporting communications enhancements, such as fifth generation (5G) new radio (NR) communications systems. In particular, 5G NR wireless communications devices incorporate the latest generation of electronic dies that are packed into smaller modules with smaller interconnections. Design challenges include integrating passive devices and active devices to implement RF front-end modules (FEMs).

RF filters in mobile RF transceivers may include high performance capacitor and inductor components. For example, RF filters use various types of passive devices, such as integrated capacitors and integrated inductors. Integrated capacitors may include metal-oxide-semiconductor (MOS) capacitors, p-n junction capacitors, metal-insulator-metal (MIM) capacitors, poly-to-poly capacitors, metal-oxide-metal (MOM) capacitors, and other like capacitor structures. Capacitors are generally passive elements used in integrated circuits for storing an electrical charge. For example, parallel plate capacitors are often made using plates or structures that are conductive with an insulating material between the plates.

An inductor is an example of an electrical device used to temporarily store energy in a magnetic field within a wire coil according to an inductance value. This inductance value provides a measure of the ratio of voltage to the rate of change of current passing through the inductor. When the current flowing through an inductor changes, energy is temporarily stored in a magnetic field in the coil. In addition to their magnetic field storing capability, inductors are often used in alternating current (AC) electronic equipment, such as radio equipment. For example, the design of mobile RF transceivers includes the use of inductors with improved inductance density while reducing magnetic loss at millimeter wave (mmW) frequencies (e.g., frequency range two (FR2)).

A radio frequency front-end (RFFE) module may include a 5G broadband FR2 filter including MIM capacitors and inductors. In practice, an RFFE module may be implemented by integrating RF filters, active devices, and surface-mount technology (SMT) devices on a laminate substrate. These RF filters, active devices, and SMT devices are conventionally arranged in a side-by-side on package configuration supported by a laminate substrate. Unfortunately, this conventional side-by-side on package laminate configuration is subjected to decreasing XY size and Z height limitations due to the reduced form factor of future RF applications. That is, the XY size and Z height dimensions of conventional side-by-side on package laminate configurations exceed the form factor of future RFFE module applications. An RFFE implementation that meets reduced XY size and Z height dimensions specified by the form factor of future RFFE module applications is desired.

Various aspects of the disclosure provide a metal-insulator-metal (MIM) capacitor interconnect for a high-quality (Q) inductor-capacitor (LC) filter. The process flow for fabrication of the MIM capacitor interconnect may include wafer-level processes, such as front-end-of-line (FEOL) processes, middle-of-line (MOL) processes, and back-end-of-line (BEOL) processes. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced. Similarly, the terms chip and die may be used interchangeably.

As described, the back-end-of-line (BEOL) interconnect layers may refer to the conductive interconnect layers (e.g., a first interconnect layer (M1) or metal one M1, metal two (M2), metal three (M3), metal four (M4), etc.) for electrically coupling to front-end-of-line (FEOL) active devices of an integrated circuit. The various BEOL interconnect layers are formed at corresponding BEOL interconnect layers, in which lower BEOL interconnect layers use thinner metal layers relative to upper BEOL interconnect levels. The BEOL interconnect layers may electrically couple to middle-of-line (MOL) interconnect layers, for example, to connect M1 to an oxide diffusion (OD) layer of an integrated circuit. The MOL interconnect layer may include a zero interconnect layer (M0) for connecting M1 to an active device layer of an integrated circuit. A BEOL first via (V2) may connect M2 to M3 or others of the BEOL interconnect layers. The BEOL vias may also provide a via pad (VP) to support package (or device) interconnects, such as package balls.

According to aspects of the present disclosure, an RF device includes a passive substrate having a first metallization layer on a first surface of the passive substrate. Additionally, the RF device includes a first passive component formed from the first metallization layer on a first surface of the passive substrate. In some aspects of the present disclosure, the RF device includes an insulator layer coupled to the first metallization layer. In these aspects of the present disclosure, the RF device includes a first conductive interconnect on the insulator layer to form a second passive component coupled to the first passive component. Additionally, a laminate substrate may be coupled to the first conductive interconnect. In some aspects of the present disclosure, the RF device is an inductor-capacitor (LC) filter. In these aspects of the present disclosure, the second passive component is a metal-insulator-metal (MIM) capacitor interconnect and the first passive component is a 2D inductor coupled to the MIM capacitor interconnect.

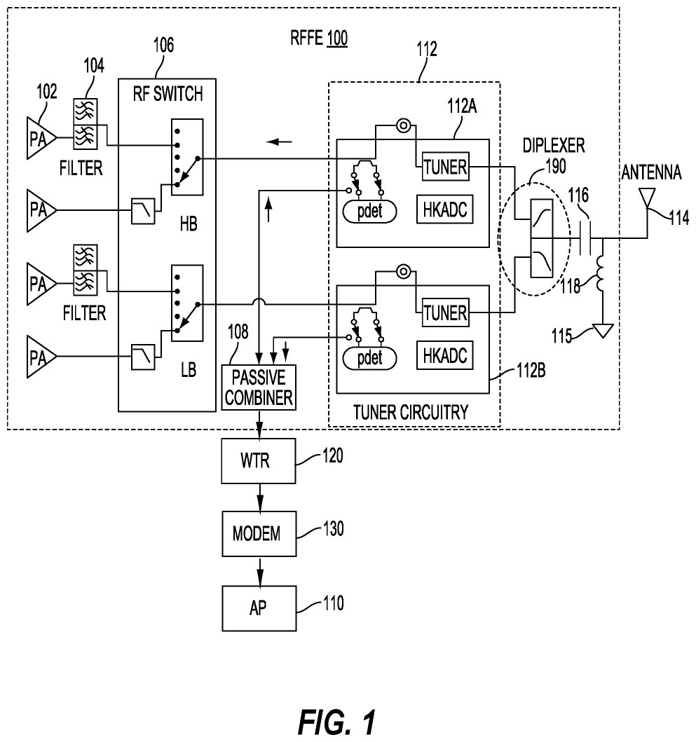

FIG. 1 is a schematic diagram of a radio frequency front-end (RFFE) module 100 employing a metal-insulator-metal (MIM) capacitor interconnect for a high-quality (Q) inductor-capacitor (LC) filter, according to aspects of the present disclosure. The RFFE module 100 includes power amplifiers 102, duplexer/filters 104, and a radio frequency (RF) switch module 106. The power amplifiers 102 amplify signal(s) to a certain power level for transmission. The duplexer/filters 104 filter the input/output signals according to a variety of different parameters, including frequency, insertion loss, rejection, or other like parameters. In addition, the RF switch module 106 may select certain portions of the input signals to pass on to the rest of the RFFE module 100.

The radio frequency front-end (RFFE) module 100 also includes tuner circuitry 112 (e.g., first tuner circuitry 112A and second tuner circuitry 112B), the diplexer 190, a capacitor 116, an inductor 118, a ground terminal 115, and an antenna 114. The tuner circuitry 112 (e.g., the first tuner circuitry 112A and the second tuner circuitry 112B) includes components such as a tuner, a portable data entry terminal (PDET), and a housekeeping analog-to-digital converter (HKADC). The tuner circuitry 112 may perform impedance tuning (e.g., a voltage standing wave ratio (VSWR) optimization) for the antenna 114. The RFFE module 100 also includes a passive combiner 108 coupled to a wireless transceiver (WTR) 120. The passive combiner 108 combines the detected power from the first tuner circuitry 112A and the second tuner circuitry 112B. The wireless transceiver 120 processes the information from the passive combiner 108 and provides this information to a modem 130 (e.g., a mobile station modem (MSM)). The modem 130 provides a digital signal to an application processor (AP) 140.

As shown in FIG. 1, the diplexer 190 is between the tuner component of the tuner circuitry 112 and the capacitor 116, the inductor 118, and the antenna 114. The diplexer 190 may be placed between the antenna 114 and the tuner circuitry 112 to provide high system performance from the radio frequency front-end (RFFE) module 100 to a chipset including the wireless transceiver 120, the modem 130, and the application processor 110. The diplexer 190 also performs frequency domain multiplexing on both high band frequencies and low band frequencies. After the diplexer 190 performs its frequency multiplexing functions on the input signals, the output of the diplexer 190 is fed to an optional inductor-capacitor (LC) network including the capacitor 116 and the inductor 118. The LC network may provide extra impedance matching components for the antenna 114, when desired. Then, a signal with the particular frequency is transmitted or received by the antenna 114. Although a single capacitor and inductor are shown, multiple components are also contemplated.

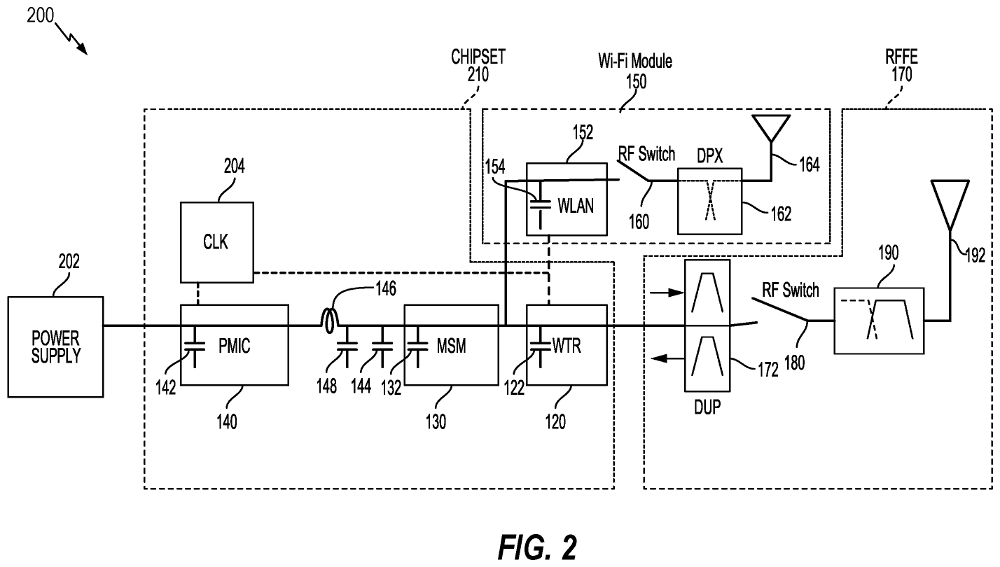

FIG. 2 is a schematic diagram of a radio frequency integrated circuit (RFIC) chip 200, having a wireless local area network (WLAN) (e.g., Wi-Fi) module 150 and a radio frequency front-end (RFFE) module 170 for a chipset 210. The Wi-Fi module 150 includes a first diplexer 162 communicably coupling an antenna 164 to a WLAN module 152. A first RF switch 160 communicably couples the first diplexer 162 to the WLAN module 152. The RFFE module 170 includes a second diplexer 190 communicably coupling an antenna 192 to a wireless transceiver (WTR) 120 through a duplexer 172. A second RF switch 180 communicably couples the second diplexer 190 to the duplexer 172.

The WTR 120 and the WLAN module 152 of the Wi-Fi module 150 are coupled to a modem (mobile station modem (MSM), e.g., baseband modem) 130 that is powered by a power supply 202 through a power management integrated circuit (PMIC) 140. The chipset 210 also includes capacitors 144 and 148, as well as an inductor(s) 146 to provide signal integrity. The PMIC 140, the modem 130, the WTR 120, and the WLAN module 152 each include capacitors (e.g., 142, 132, 122, and 154) and operate according to a clock 204. In addition, the inductor 146 couples the modem 130 to the PMIC 140. The geometry and arrangement of the various inductor and capacitor components in the RFIC) chip 200 may reduce the electromagnetic coupling between the components.

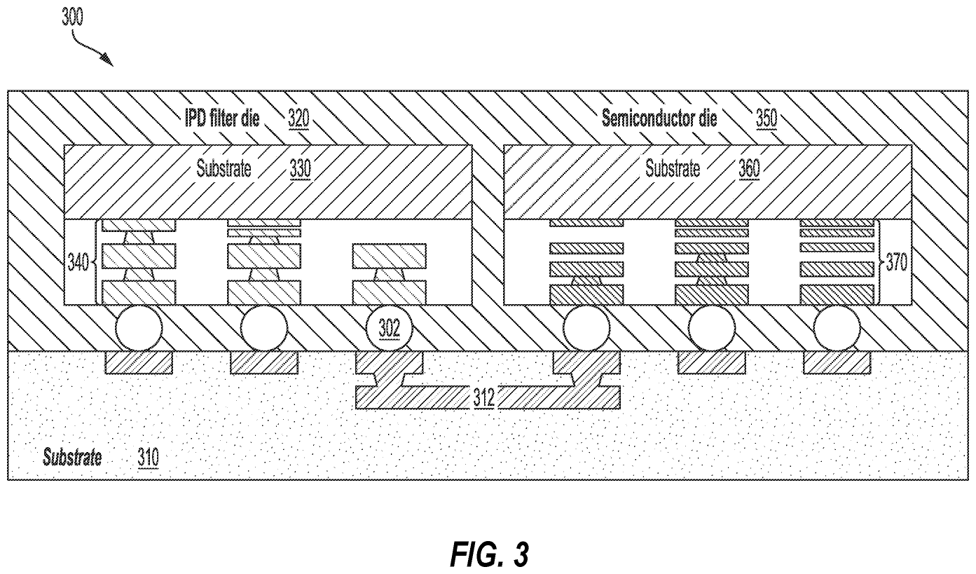

The WTR 120 of the wireless device generally includes a mobile RF transceiver to transmit and receive data for two-way communications. The WTR 120 and the RFFE module 170 may be implemented using high performance complementary metal oxide semiconductor (CMOS) RF switch technologies to implement switch transistors of the first RF switch 160 and the second RF switch 180. The RFFE module 170 may rely on these high-performance CMOS RF switch technologies to implement an active die for successful operation. In practice, the active die used to implement the CMOS RF switch technology may involve integration with a passive RF filter to implement an antenna module, for example, as shown in FIG. 3.

FIG. 3 is a block diagram illustrating a cross-sectional view of a radio frequency front-end (RFFE) module 300 including a semiconductor die 350 and an integrated passive device (IPD) filter die 320, in accordance with aspects of the present disclosure. In this example, the RFFE module 300 includes the semiconductor die 350 and the IPD filter die 320 supported by a package substrate 310 (e.g., a laminate substrate). The semiconductor die 350 may be an active die having a semiconductor substrate 360 (e.g., an active silicon substrate) coupled to package balls 302 through back-end-of-line (BEOL) layers 370. The BEOL layers 370 include multiple BEOL metallization layers (M1, M2, M3, . . . , Mn) on the semiconductor substrate 360 (e.g., a diced silicon wafer). A redistribution layer 312 is coupled to the package balls 302.

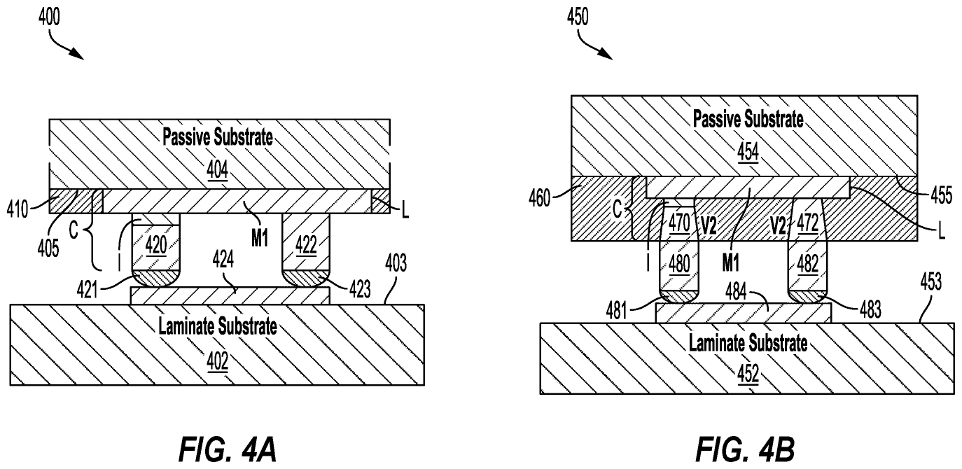

The IPD filter die 320 includes a substrate 330 (e.g., a passive substrate) coupled to the package balls 302 through back-end-of-line (BEOL) layers 340. The redistribution layer 312 is coupled to the IPD filter die 320 through the package balls 302. In some aspects of the present disclosure, the substrate 330 is composed of glass, and the IPD filter die 320 is a glass-substrate integrated passive device (GIPD) filter die. In practice, the RFFE module 300 integrates the IPD filter die 320, the semiconductor die 350, and surface-mount technology (SMT) devices on the package substrate 310 (e.g., laminate). The IPD filter die 320, the semiconductor die 350, and the SMT devices (not shown) are arranged in a side-by-side on package configuration supported by the package substrate 310. Unfortunately, this side-by-side on package substrate configuration is subjected to decreasing XY size and Z height limitations due to the reduced form factor of future RF applications. That is, the XY size and Z height dimensions of conventional side-by-side on package laminate configurations exceed the form factor of future RFFE module applications. An RFFE implementation that meets reduced XY size and Z height dimensions specified by the form factor of future RFFE module applications is shown, for example, in FIGS. 4A and 4B.

FIGS. 4A and 4B are block diagrams illustrating radio frequency (RF) devices including metal-insulator-metal (MIM) capacitor interconnects for high-quality (Q) inductor-capacitor (LC) filters, according to aspects of the present disclosure. As shown in FIG. 4A, an RF device 400 includes a passive substrate 404, which may be composed of glass or other like substrate material. In this example, the passive substrate includes interlayer dielectric (ILD) layers 410 formed of, for example, polyimide, on a first surface 405 of the passive substrate 404. In some aspects of the present disclosure, a 2D inductor L is formed within the ILD layers 410. The 2D inductor Lis formed from a back-end-of-line (BEOL) metallization layer M1 on the first surface 405 of the passive substrate 404.

In these aspects of the present disclosure, a first plate of a metal-insulator-metal (MIM) capacitor C is also formed from the M1 metallization layer. The MIM capacitor C includes an insulator layer I formed on the first plate portion of the metallization layer M1. A first conductive pillar 420 (e.g., a copper (Cu) pillar) is formed on the insulator layer I to complete formation of the MIM capacitor C. In this example, the first conductive pillar 420 is contacted to a first conductive trace 424 on a first surface 403 of a laminate substrate 402 through a conductive bump 421. In some aspects of the present disclosure, the laminate substrate 402 is implemented as a printed circuit board (PCB) and the first conductive trace 424 (e.g., a PCB trace) is also formed from a first metallization layer M1. Additionally, the RF device 400 includes a second conductive pillar 422 coupled between the first metallization layer M1 and the first conductive trace 424 using a conductive bump 423.

In this example, the MIM capacitor C is formed using a plate of the M1 metallization layer and the first conductive pillar 420, below an M3 metallization layer using an insulation layer (I) that is not available during fabrication of organic laminate substrates such as silicon nitride (SiN) or other like dielectric material. The MIM capacitor C and the 2D inductor L provide passive components (e.g., an inductor-capacitor (LC) filter of the RF device 400) that may be interconnected to provide an RF filter as well as surface-mount technology (SMT) matching passive components of the RF device 400, such as a radio frequency (RF) inductor-capacitor (LC) filter. This configuration of the RF device 400 provides a reduced 3D stack height as well as a reduced mask count.

FIG. 4B is a block diagram illustrating an RF device 450 including a MIM capacitor interconnect for a high-Q LC filter, according to aspects of the present disclosure. Representatively, the RF device 450 also includes a passive substrate 454, including ILD layers 460 formed of, for example, polyimide, on a first surface 455 of the passive substrate 454. In this example, the ILD layers 460 also include a 2D inductor L formed from the BEOL metallization layer M1 on the first surface 455 of the passive substrate 454. In this example, the metallization layer M1 also provides a first plate of a MIM capacitor C, including an insulator layer I formed on a portion of the metallization layer M1.

In some aspects of the present disclosure, a first conductive via 470 is formed on the insulator layer I to complete formation of the MIM capacitor C. Additionally, a first conductive pillar 480 is formed on the first conductive via 470 and contacted to a conductive trace 484 on a first surface 453 of a laminate substrate 452 through a first conductive bump 481. In this example, the RF device 450 includes a second conductive via 472 coupled to the first metallization layer M1 and a second conductive pillar 482 (e.g., a second conductive interconnect) formed on the second conductive via 472 and secured to the conductive trace 484 using a second conductive bump 483. This configuration of the RF device 450 also provides a reduced 3D stack height as well as a further reduced mask count.

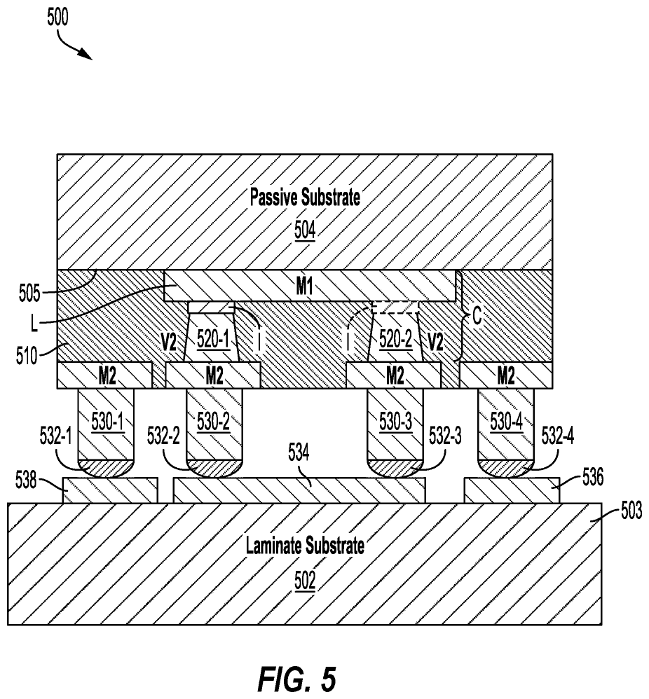

FIG. 5 is a block diagram illustrating a radio frequency (RF) device 500 including a metal-insulator-metal (MIM) capacitor interconnect for a high-quality (Q) inductor-capacitor (LC) filter, according to aspects of the present disclosure. As shown in FIG. 5, the RF device 500 includes a passive substrate 504, which may be composed of glass or other like substrate material. In this example, the passive substrate 504 includes interlayer dielectric (ILD) layers 510 formed of, for example, polyimide, on a first surface 505 of the passive substrate 504. In this example, the ILD layers 510 also include a 2D inductor L formed from a first BEOL metallization layer M1 on the first surface 505 of the passive substrate 504.

In this example, the metallization layer M1 provides a first plate of a MIM capacitor C. In this configuration, the MIM capacitor C also includes an insulator layer I formed on a portion of the metallization layer M1. In some aspects of the present disclosure, a first conductive via 520-1 is formed on the insulator layer I to complete formation of the MIM capacitor C, such as a MIM capacitor via. Additionally, the first conductive via 520-1 is contacted to a second metallization layer M2. In some aspects of the present disclosure, an optional insulator layer I is deposited on a second portion of the metallization layer M1 to support a second conductive via 520-2, which is also contacted to a second metallization layer M2. This aspect of the present disclosure provides series MIM capacitor vias.

This configuration of the RF device 500 includes a laminate substrate 502, having a first conductive trace 534, a second conductive trace 536, and a third conductive trace 538 on a first surface 503 of a laminate substrate 502 through conductive bumps 532 (532-1, 532-2, 532-3, and 532-4). The laminate substrate 502 may be implemented using a printed circuit board (PCB) and the first conductive trace 534, second conductive trace 536, and the third conductive trace 538 are also formed from a first metallization layer M1. Additionally, the RF device 500 includes conductive pillars 530 (530-1, 530-2, 530-3, and 530-4) having a first surface and a second surface coupled between the second metallization layers M2 and the conductive traces (e.g., 534, 536, and 538) using conductive bumps 532 (532-1, 532-2, 532-3, and 532-4). This configuration of the RF device 500 also provides a reduced 3D stack height as well as a reduced mask count by eliminating a redistribution layer (RDL) during fabrication.

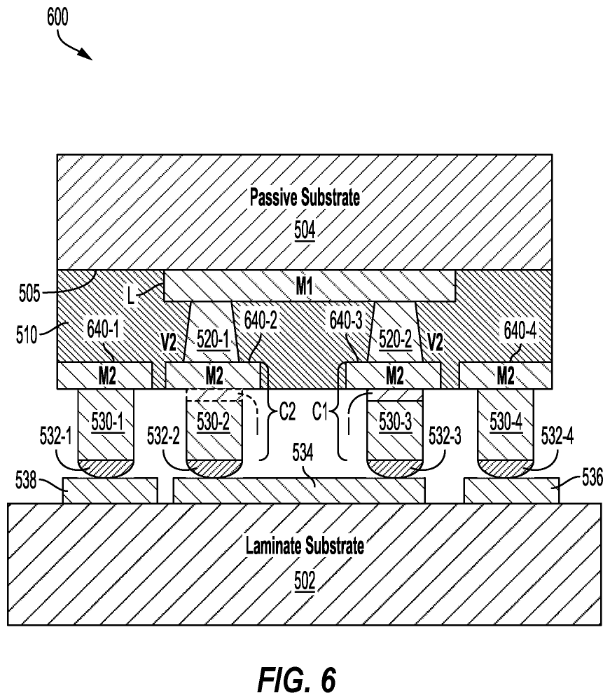

FIG. 6 is a block diagram further illustrating the radio frequency (RF) device including a metal-insulator-metal (MIM) capacitor interconnect for a high-quality (Q) inductor-capacitor (LC) filter, according to further aspects of the present disclosure. As shown in FIG. 6, an RF device 600 is similar to the RF device 500 of FIG. 5 and described using similar reference numbers. As shown in FIG. 6, the RF device 600 includes a second metallization layer M2 640, including a first portion 640-1, a second portion 640-2, a third portion 640-3, and a fourth portion 640-4. In this aspect of the present disclosure, the third portion 640-3 of the second metallization layer M2 640 provides a first plate of a first MIM capacitor C1. In this configuration, the first MIM capacitor C1 includes an insulator layer I formed on the third portion 640-3 of the second metallization layer M2 640. Additionally, a third conductive pillar 530-3 is formed on the insulator layer I to complete formation of the first MIM capacitor C1, such as a MIM capacitor pillar.

In some aspects of the present disclosure, an optional insulator layer I is deposited on the second portion 640-2 of the second metallization layer M2 640 to support the second conductive pillar 530-2 to form the second MIM capacitor C2. Additionally, the first MIM capacitor C1 and the second MIM capacitor C2 also contacted to a first conductive trace 534 of the laminate substrate 502 through the conductive bumps 532 (e.g., 532-2 and 532-3). In this example, the conductive bumps 532 may be formed by depositing tin (Sn) solder or reflowing tin silver (SnAg) on the conductive pillars 530. In some aspects of the present disclosure, in which the laminate substrate 502 is implemented as a printed circuit board (PCB), the conductive bumps 532 may be implemented as package balls that may be part of a land grid array (LGA), a ball grid array (BGA), or other like interconnect structure. This aspect of the present disclosure provides series MIM capacitor pillars.

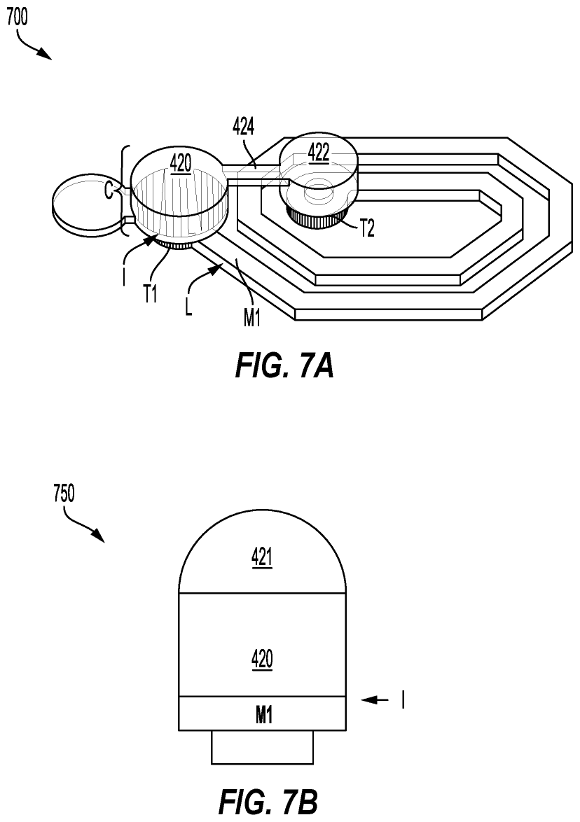

FIGS. 7A and 7B are block diagrams further illustrating the radio frequency (RF) devices of FIGS. 4A and 4B, according to aspects of the present disclosure. As shown in FIG. 7A, an RF device 700 is similar to the RF device 400 of FIG. 4A and is described using similar reference numbers. In FIG. 7A, the 2D inductor L is shown in a semi-spiral configuration, having a first terminal T1 and a second terminal T2. In this configuration, the MIM capacitor C includes an insulator layer I formed on a portion of the metallization layer M1. Additionally, a first conductive pillar 420 is formed on the insulator layer I to complete formation of the MIM capacitor C. In this example, the first conductive pillar 420 is contacted to the second conductive pillar 422 through the first conductive trace 424.

FIG. 7B is a block diagram further illustrating a MIM capacitor pillar of FIG. 4B, according to aspects of the present disclosure. As shown in FIG. 7B, a MIM capacitor pillar 750 is composed of the insulator layer I on the metallization layer M1. Additionally, the first conductive pillar 420 is formed on the insulator layer I. The MIM capacitor pillar 750 is completed by forming the conductive bump 421 on the first conductive pillar 420. In this example, the conductive bump 421 may be formed by depositing tin (Sn) solder or reflowing tin silver (SnAg) on the first conductive pillar 420.

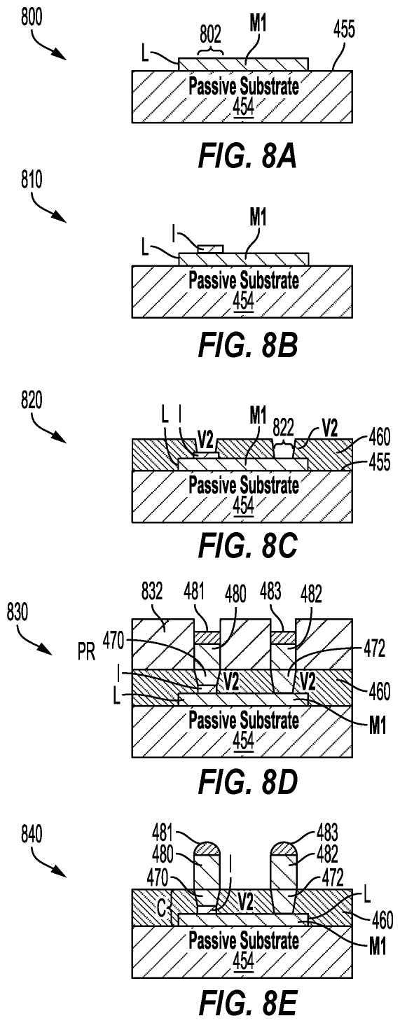

This configuration of the MIM capacitor pillar 750 provides a significant (e.g., 20%) form factor reduction from a reduced capacitor area (e.g., 7.85 mm²) with a reduced diameter (e.g., 100 microns). Additionally, an LC filter of the RF device 700 provides an improved insertion loss (e.g., −20.71 db @ 5.16 GHZ) and the MIM capacitor pillar 750 provides an improved Q-factor (e.g., 44.75 @ 7 GHZ). This configuration of the MIM capacitor pillar 750 provides an improved thermal heat dissipation path, while reducing manufacturing of the MIM capacitor pillar 750 to one mask, which provides a significant (e.g., 20%) cost reduction. A process for fabrication of an RF device including a MIM conductive interconnect is shown, for example, in FIGS. 8A-8E.

FIGS. 8A-8E are block diagrams illustrating a process of fabricating the RF device 450 of FIG. 4B, including a MIM capacitor interconnect for a high-quality (Q) inductor-capacitor (LC) filter, according to aspects of the present disclosure. As shown in FIG. 8A, at step 800, the M1 metallization layer is plated on the first surface 455 of the passive substrate 454. As noted in FIG. 4B, a 2D inductor is also formed during plating of the M1 metallization layer, for example, as shown in FIG. 7A. A first portion 802 of the M1 metallization layer is identified to enable deposition of the insulator layer I, as shown in FIG. 8B.

As shown in FIG. 8B, at step 810, the insulator layer I is deposited on the first portion 802 of the metallization layer M1, which may be formed through a silicon nitride (SiN) deposition, or other like dielectric layer deposition. As shown in FIG. 8C, at step 820, the ILD layers 460 are formed on the first surface 455 of the passive substrate 454 and on the metallization layer M1. Additionally, second BEOL via (V2) openings are formed in the ILD layers 460 to expose the insulator layer I as well as a second portion 822 of the first metallization layer. In some aspects of the present disclosure, a size of the V2 opening exposing the insulator layer I is determined based on a desired capacitance value of the MIM capacitor interconnect C. For contact formation on the second portion 822 of the M1 metallization layer, the V2 opening is a uniform size.

As shown in FIG. 8D, at step 830, a photoresist (PR) layer 832 is deposited on the ILD layers 460 and patterned according to the V2 openings to expose the insulator layer I and the second portion 822 of the M1 metallization layer. Once exposed, an under metallization (UM) process is performed to form the first conductive via 470 on the insulator layer I, and the second conductive via 472 on the second portion 822 of the M1 metallization layer. The under-metallization process also forms the first conductive pillar 480 on the first conductive via 470 and the second conductive pillar 482 on the second conductive via 472. Additionally, the first conductive bump 481 is formed on the first conductive pillar 480, and the second conductive bump 483 is formed on the second conductive pillar 482.

As shown in FIG. 8E, at step 840, the PR layer 832 is removed from the ILD layers 460. Additionally, the first conductive bump 481 and the second conductive bump 483 are reflowed on the first conductive pillar 480 and the second conductive pillar 482. Completion of the RF device 450 includes securing the first conductive bump 481 and the second conductive bump 483 to the conductive trace 484 on the laminate substrate 452, as shown in FIG. 4B.

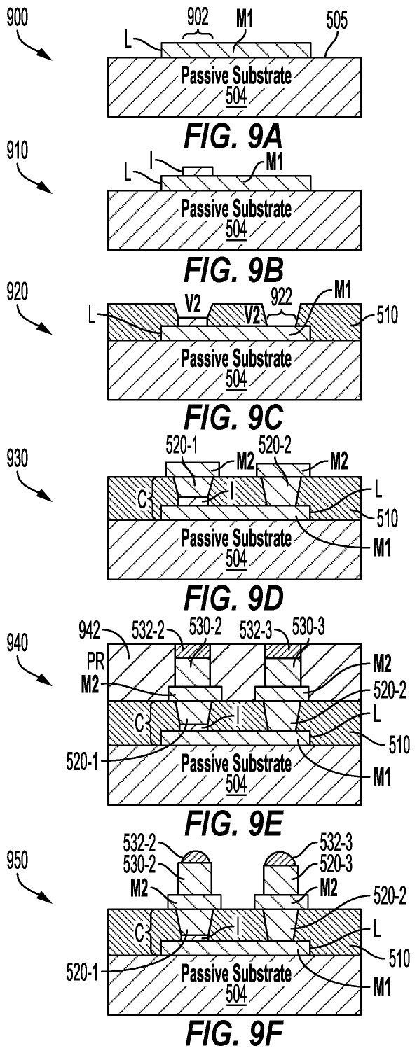

FIGS. 9A-9F are block diagrams illustrating a process of fabricating the RF device 500 of FIG. 5, including a MIM capacitor interconnect for a high-quality (Q) inductor-capacitor (LC) filter, according to aspects of the present disclosure. As shown in FIG. 9A, at step 900, the M1 metallization layer is plated on the first surface 505 of the passive substrate 504. As noted with respect to FIG. 5, a 2D inductor is also formed during plating of the M1 metallization layer, for example, as shown in FIG. 7A. A first portion 902 of the M1 metallization layer is identified to enable deposition of the insulator layer I, as shown in FIG. 9B.

As shown in FIG. 9B, at step 910, the insulator layer I is deposited on the first portion 902 of the metallization layer M1, which may be formed through a silicon nitride (SiN) deposition, or other like dielectric layer deposition. As shown in FIG. 9C, at step 920, the ILD layers 510 are formed on the first surface 505 of the passive substrate 504 and on the metallization layer M1. Additionally, second BEOL via (V2) openings are formed in the ILD layers 510 to expose the insulator layer I as well as a second portion 922 of the first metallization layer M1. In some aspects of the present disclosure, a size of the V2 opening exposing the insulator layer I is determined based on a desired capacitance value of the MIM capacitor interconnect C. For contact formation on the second portion 922 of the first M1 metallization layer, the V2 opening is a uniform size.

As shown in FIG. 9D, at step 930, a second metallization layer process forms the first conductive via 520-1 and the second conductive via 520-2. Additionally, the second metallization layer process forms an M2 metallization layer on the first conductive via 520-1 and an M2 metallization layer on the second conductive via 520-2. The M2 metallization layers are also formed on portions of the surface of the ILD layers 510, for example, as shown in FIGS. 5 and 6.

As shown in FIG. 9E, at step 940, a photoresist (PR) layer 942 is deposited on the ILD layers 510 and the M2 metallization layers. Once deposited, the PR layer 942 is patterned according to dimensions of the second conductive pillar 530-2 and the third conductive pillar 530-3. Once patterned, an under metallization (UM) process is performed to form the second conductive pillar 530-2 and the third conductive pillar 530-3 on the M2 metallization layers. Additionally, a second conductive bump 532-2 is formed on the second conductive pillar 530-2, and a third conductive bump 532-3 is formed on the third conductive pillar 530-3.

As shown in FIG. 9F, at step 950, the PR layer 942 is removed from the ILD layers 510. Additionally, the second conductive bump 532-2 and the third conductive bump 532-3 are reflowed on the second conductive pillar 530-2 and the third conductive pillar 530-3. Completion of the RF device 500 includes securing the second conductive bump 532-2 and the third conductive bump 532-3 to the first conductive trace 534 and the second conductive trace 536 on the laminate substrate 502, as shown in FIG. 5.

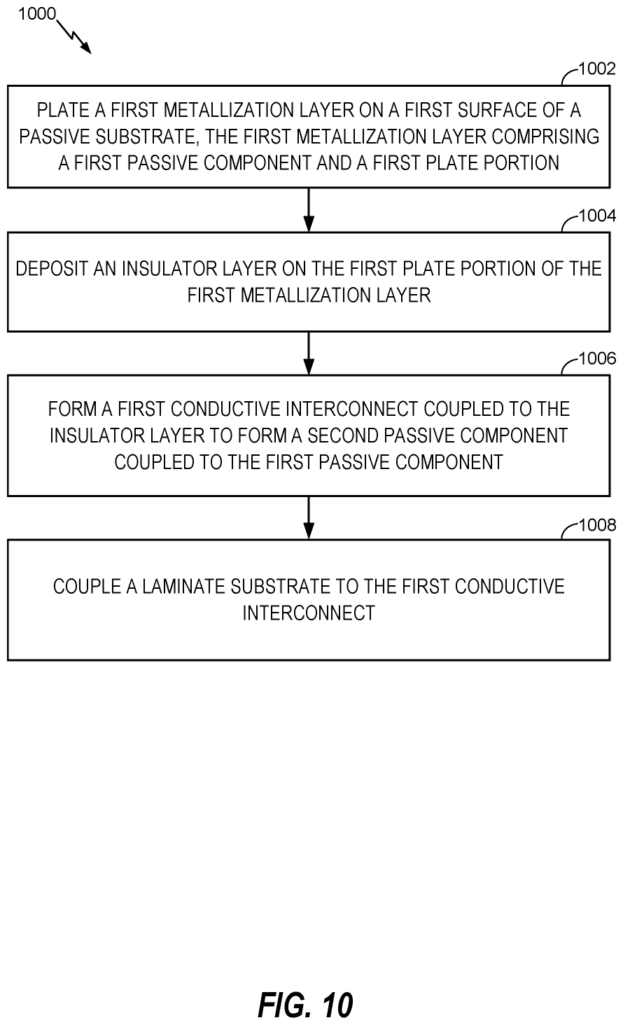

FIG. 10 is a process flow diagram illustrating a method 1000 for fabricating a radio frequency (RF) device, including a metal-insulator-metal (MIM) capacitor interconnect for a high-quality (Q) inductor-capacitor (LC) filter, according to aspects of the present disclosure. The method 1000 begins at block 1002, in which a first metallization layer is plated on a first surface of a passive substrate, in which the first metallization layer is composed of a first passive component and a first plate portion. For example, as shown in FIG. 9A, at step 900, the M1 metallization layer is plated on the first surface 505 of the passive substrate 504. As noted with respect to FIG. 5, a 2D inductor is also formed during plating of the M1 metallization layer, for example, as shown in FIG. 7A. A first portion 902 of the M1 metallization layer is identified to enable deposition of the insulator layer I, as shown in FIG. 9B.

At block 1004, an insulator layer is deposited on the first plate portion of the first metallization layer. For example, as shown in FIG. 9B, at step 910 the insulator layer I is deposited on the first portion 902 of the metallization layer M1, which may be formed through a silicon nitride (SiN) deposition, or other like dielectric layer deposition. As shown in FIG. 9C, at step 920, the ILD layers 510 are formed on the first surface 505 of the passive substrate 504 and on the metallization layer M1.

At block 1006, a first conductive interconnect is formed and coupled to the insulator layer to form a second passive component coupled to the first passive component. For example, as shown in FIG. 9B, second BEOL via (V2) openings are formed in the ILD layers 510 to expose the insulator layer I as well as a second portion 922 of the first metallization layer M1. In some aspects of the present disclosure, a size of the V2 opening exposing the insulator layer I is determined based on a desired capacitance value of the MIM capacitor interconnect C. For contact formation on the second portion 922 of the first M1 metallization layer, the V2 opening is a uniform size. As shown in FIG. 8D, at step 830 the PR layer 832 is deposited on the ILD layers 460 and patterned according to the V2 openings to expose the insulator layer I and the second portion 822 of the M1 metallization layer. Once exposed, the UM process is performed to form the first conductive via 470 on the insulator layer I, and the second conductive via 472 on the second portion 822 of the M1 metallization layer. The under-metallization process also forms the first conductive pillar 480 on the first conductive via 470 and the second conductive pillar 482 on the second conductive via 472. Additionally, the first conductive bump 481 is formed on the first conductive pillar 480, and the second conductive bump 483 is formed on the second conductive pillar 482.

At block 1008, a laminate substrate is coupled to the first conductive interconnect. For example, as shown in FIG. 4B, the first conductive via 470 is formed on the insulator layer I to complete formation of the MIM capacitor C. Additionally, a first conductive pillar 480 is formed on the first conductive via 470 and contacted to a conductive trace 484 on a first surface 453 of a laminate substrate 452 through a first conductive bump 481. In this example, the RF device 450 includes a second conductive via 472 coupled to the first metallization layer M1 and a second conductive pillar 482 (e.g., a second conductive interconnect) formed on the second conductive via 472 and secured to the conductive trace 484 using a second conductive bump 483. This configuration of the RF device 450 also provides a reduced 3D stack height as well as a further reduced mask count.

In some aspects of the present disclosure, a MIM capacitor interconnect provides a high-Q passive LC filter in an RF device. In some aspects of the present disclosure, a the MIM capacitor interconnect is implemented as a MIM capacitor via as well as a MIM capacitor pillar. This configuration of a MIM capacitor interconnect provides a significant (e.g., 20%) form factor reduction by consuming a reduced capacitor area (e.g., 7.85 mm²) with a reduced diameter (e.g., 100 microns). Additionally, an LC filter of an RF device 700 including a MIM capacitor interconnect provides an improved insertion loss (e.g., −20.71 db @ 5.16 GHZ) and the MIM capacitor interconnect provides an improved Q-factor (e.g., 44.75 @ 7 GHZ). Additionally, the MIM capacitor interconnect configuration provides an improved thermal heat dissipation path, while reducing manufacturing of the MIM capacitor via to one mask, which provides a significant (e.g., 20%) cost reduction.

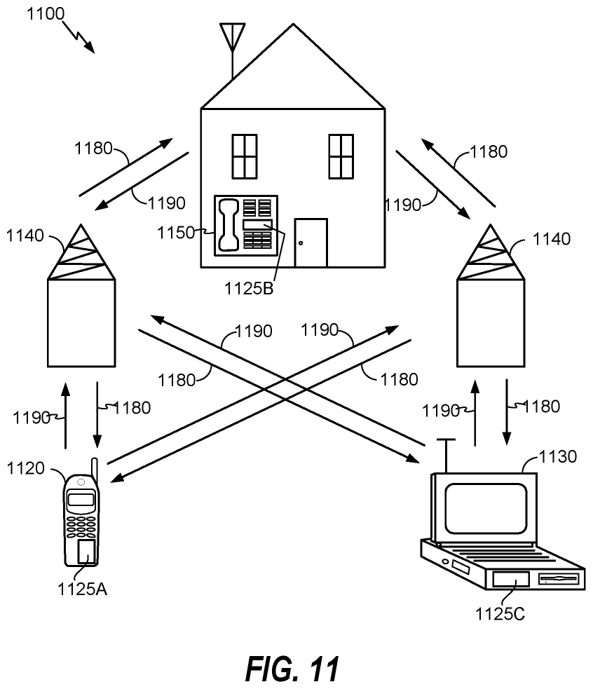

FIG. 11 is a block diagram showing an exemplary wireless communications system 1100 in which an aspect of the disclosure may be advantageously employed. For purposes of illustration, FIG. 11 shows three remote units 1120, 1130, and 1150 and two base stations 1140. It will be recognized that wireless communications systems may have many more remote units and base stations. Remote units 1120, 1130, and 1150 include integrated circuit (IC) devices 1125A, 1125C, and 1125B that include the disclosed MIM capacitor interconnect. It will be recognized that other devices may also include the disclosed MIM capacitor interconnect, such as the base stations, switching devices, and network equipment. FIG. 11 shows forward link signals 1180 from the base station 1140 to the remote units 1120, 1130, and 1150, and reverse link signals 1190 from the remote units 1120, 1130, and 1150 to the base stations 1140.

In FIG. 11, remote unit 1120 is shown as a mobile telephone, remote unit 1130 is shown as a portable computer, and remote unit 1150 is shown as a fixed location remote unit in a wireless local loop system. For example, the remote units may be a mobile phone, a hand-held personal communication systems (PCS) unit, a portable data unit, such as a personal data assistant, a GPS enabled device, a navigation device, a set top box, a music player, a video player, an entertainment unit, a fixed location data unit, such as meter reading equipment, or other device that stores or retrieves data or computer instructions, or combinations thereof. Although FIG. 11 illustrates remote units according to the aspects of the present disclosure, the present disclosure is not limited to these exemplary illustrated units. Aspects of the present disclosure may be suitably employed in many devices, which include the disclosed MIM capacitor interconnect.

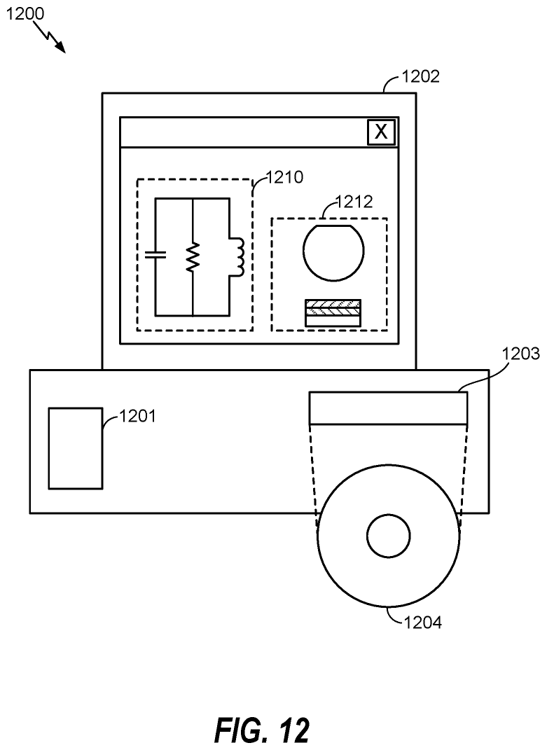

FIG. 12 is a block diagram illustrating a design workstation used for circuit, layout, and logic design of a semiconductor component, such as the MIM capacitor interconnect disclosed above. A design workstation 1200 includes a hard disk 1201 containing operating system software, support files, and design software such as Cadence or OrCAD. The design workstation 1200 also includes a display 1202 to facilitate design of a circuit 1210 or a radio frequency (RF) component 1212 such as an RDL substrate. A storage medium 1204 is provided for tangibly storing the design of the circuit 1210 or the RF component 1212 (e.g., the RDL substrate). The design of the circuit 1210 or the RF component 1212 may be stored on the storage medium 1204 in a file format such as GDSII or GERBER. The storage medium 1204 may be a compact disc read-only memory (CD-ROM), digital versatile disc (DVD), hard disk, flash memory, or another appropriate device. Furthermore, the design workstation 1200 includes a drive apparatus 1203 for accepting input from or writing output to the storage medium 1204.

Data recorded on the storage medium 1204 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1204 facilitates the design of the circuit 1210 or the RF component 1212 by decreasing the number of processes for designing semiconductor wafers.

Implementation examples are described in the following numbered clauses:
1. A device, comprising:
a passive substrate having a first metallization layer on a first surface of the passive substrate, the first metallization layer comprising a first passive component and a first plate portion;
an insulator layer coupled to the first plate portion of the first metallization layer;
a first conductive interconnect coupled to the insulator layer to form a second passive component coupled to the first passive component; and
a laminate substrate coupled to the first conductive interconnect.
2. The device of clause 1, in which the second passive component comprises a metal-insulator-metal (MIM) capacitor, comprising:
the first plate portion of the first metallization layer;
the insulator layer directly on the first plate portion of the first metallization layer; and
the first conductive interconnect having a first surface directly on the insulator layer and a second surface coupled to a conductive trace on the laminate substrate.
3. The device of clause 2, further comprising a second conductive interconnect having a first surface directly coupled to the first conductive interconnect, and a second surface coupled to the conductive trace on the laminate substrate.
4. The device of clause 1, in which the second passive component comprises a metal-insulator-metal (MIM) capacitor, comprising:
a second metallization layer coupled to the first metallization layer by a second conductive interconnect;
the insulator layer directly on a portion of a first surface of the second metallization layer, opposite the second conductive interconnect; and
the first conductive interconnect having a first surface directly on the insulator layer and a second surface coupled to a conductive trace on the laminate substrate.
5. The device of any of clauses 1-4, in which the second passive component comprises a metal-insulator-metal (MIM) capacitor and the first passive component comprises a 2D inductor.
6. The device of clause 1, clause 4, or clause 5, in which the first conductive interconnect comprises a copper (Cu) pillar.
7. The device of any of clauses 1-3 and clause 5, in which the first conductive interconnect comprises a copper (Cu) via.
8. The device of any of clauses 1-7, in which the laminate substrate comprises a printed circuit board (PCB) having a PCB trace coupled to the first conductive interconnect.
9. The device of any of clauses 1-8, in which the passive substrate comprises glass.
10. The device of any of clauses 1-9, in which the device comprises a radio frequency (RF) inductor-capacitor (LC) filter.
11. The device of clause 10, in which the RF LC filter is incorporated in a radio frequency front-end (RFFE) module.
12. A method for fabricating a radio frequency (RF) device, comprising:
plating a first metallization layer on a first surface of a passive substrate, the first metallization layer comprising a first passive component and a first plate portion;
depositing an insulator layer on the first plate portion of the first metallization layer;
forming a first conductive interconnect coupled to the insulator layer to form a second passive component coupled to the first passive component; and
coupling a laminate substrate to the first conductive interconnect.
13. The method of clause 12, in which forming the first conductive interconnect comprises:
forming via openings in interlayer dielectric (ILD) layers on the passive substrate to expose the insulator layer as well as a second plate portion of the first metallization layer; and
forming a first via on the insulator layer, and a second via on the second plate portion of the first metallization layer.
14. The method of clause 13, further comprising:
depositing and patterning a photoresist (PR) layer on the ILD layers on the passive substrate to expose the first via and the second via;
forming a first conductive pillar on the first via and a second conductive pillar on the second via; and
forming a first bump on the first conductive pillar and a second bump on the second conductive pillar.
15. The method of clause 14, in which forming the first bump on the first conductive pillar and the second bump on the second conductive pillar further comprises:
removing the PR layer from the ILD layers to expose the first conductive pillar on the first via and the second conductive pillar on the second via; and
reflowing the first bump on the first conductive pillar and the second bump on and the second conductive pillar.
16. The method of clause 13, further comprising:
forming a second metallization layer on the first via and on the second via;
depositing and patterning a photoresist (PR) layer on the ILD layers on the passive substrate to expose the second metallization layer;
forming a first conductive pillar on the second metallization layer on the first via and a second conductive pillar on the second metallization layer on the second via; and
forming a first bump on the first conductive pillar and a second bump on the second conductive pillar.
17. The method of clause 16, in which forming the first bump on the first conductive pillar and the second bump on the second conductive pillar further comprises:
removing the PR layer from the ILD layers to expose the first conductive pillar on the second metallization layer and the second conductive pillar on the second metallization layer; and
reflowing the first bump on the first conductive pillar and the second bump on and the second conductive pillar.
18. The method of any of clauses 12-17, in which the passive substrate comprises glass.
19. The method of any of clauses 12-18, in which the RF device comprises an RF inductor-capacitor (LC) filter.
20. The method of clause 19, in which the RF LC filter is incorporated in a radio frequency front-end (RFFE) module.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include random access memory (RAM), read-only memory (ROM), electrically erasable programmable read-only memory (EEPROM), compact disc read-only memory (CD-ROM) or other optical disk storage, magnetic disk storage or other magnetic storage devices, or other medium that can be used to store desired program code in the form of instructions or data structures and that can be accessed by a computer. Disk and disc, as used herein, include compact disc (CD), laser disc, optical disc, digital versatile disc (DVD), floppy disk and Blu-ray® disc, where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, composition of matter, means, methods, and steps described in the specification. As one of ordinary skill in the art will readily appreciate from the disclosure, processes, machines, manufacture, compositions of matter, means, methods, or steps, presently existing or later to be developed that perform substantially the same function, or achieve substantially the same result as the corresponding configurations described herein, may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described herein. A general-purpose processor may be a microprocessor, but, in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the present disclosure may be embodied directly in hardware, in a software module executed by a processor, or in a combination of the two. A software module may reside in random access memory (RAM), flash memory, read-only memory (ROM), erasable programmable read-only memory (EPROM), electrically erasable programmable read-only memory (EEPROM), registers, hard disk, a removable disk, a compact disc read-only memory (CD-ROM), or any other form of storage medium known in the art. An exemplary storage medium is coupled to the processor such that the processor can read information from, and write information to, the storage medium. In the alternative, the storage medium may be integral to the processor. The processor and the storage medium may reside in an application-specific integrated circuit (ASIC). The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general-purpose or special-purpose computer. By way of example, and not limitation, such computer-readable media can include random access memory (RAM), read-only memory (ROM), electrically erasable programmable read-only memory (EEPROM), compact disc read-only memory (CD-ROM) or other optical disk storage, magnetic disk storage or other magnetic storage devices, or any other medium that can be used to carry or store specified program code means in the form of instructions or data structures and that can be accessed by a general-purpose or special-purpose computer, or a general-purpose or special-purpose processor. In addition, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include compact disc (CD), laser disc, optical disc, digital versatile disc (DVD), floppy disk, and Blu-ray® disc, where disks usually reproduce data magnetically, while discs reproduce data optically with lasers. Combinations of the above should also be included within the scope of computer-readable media.

The previous description of the present disclosure is provided to enable any person skilled in the art to make or use the disclosure. Various modifications to the present disclosure will be readily apparent to those skilled in the art, and the generic principles defined herein may be applied to other variations without departing from the spirit or scope of the disclosure. Thus, the present disclosure is not intended to be limited to the examples and designs described herein but is to be accorded the widest scope consistent with the principles and novel features disclosed herein.

What is claimed is:

1. A device, comprising:
a passive substrate having a first metallization layer on a first surface of the passive substrate, the first metallization layer comprising a first passive component and a first plate portion;
an insulator layer coupled to the first plate portion of the first metallization layer;
a first conductive interconnect coupled to the insulator layer to form a second passive component coupled to the first passive component; and
a laminate substrate coupled to the first conductive interconnect.

2. The device of claim 1, in which the second passive component comprises a metal-insulator-metal (MIM) capacitor, comprising:
the first plate portion of the first metallization layer;
the insulator layer directly on the first plate portion of the first metallization layer; and
the first conductive interconnect having a first surface directly on the insulator layer and a second surface coupled to a conductive trace on the laminate substrate.

3. The device of claim 2, further comprising a second conductive interconnect having a first surface directly coupled to the first conductive interconnect, and a second surface coupled to the conductive trace on the laminate substrate.

4. The device of claim 1, in which the second passive component comprises a metal-insulator-metal (MIM) capacitor, comprising:
a second metallization layer coupled to the first metallization layer by a second conductive interconnect;
the insulator layer directly on a portion of a first surface of the second metallization layer, opposite the second conductive interconnect; and
the first conductive interconnect having a first surface directly on the insulator layer and a second surface coupled to a conductive trace on the laminate substrate.

5. The device of claim 1, in which the second passive component comprises a metal-insulator-metal (MIM) capacitor and the first passive component comprises a 2D inductor.

6. The device of claim 1, in which the first conductive interconnect comprises a copper (Cu) pillar.

7. The device of claim 1, in which the first conductive interconnect comprises a copper (Cu) via.

8. The device of claim 1, in which the laminate substrate comprises a printed circuit board (PCB) having a PCB trace coupled to the first conductive interconnect.

9. The device of claim 1, in which the passive substrate comprises glass.

10. The device of claim 1, in which the device comprises a radio frequency (RF) inductor-capacitor (LC) filter.

11. The device of claim 10, in which the RF LC filter is incorporated in a radio frequency front-end (RFFE) module.

12. A method for fabricating a radio frequency (RF) device, comprising:
plating a first metallization layer on a first surface of a passive substrate, the first metallization layer comprising a first passive component and a first plate portion;
depositing an insulator layer on the first plate portion of the first metallization layer;
forming a first conductive interconnect coupled to the insulator layer to form a second passive component coupled to the first passive component; and
coupling a laminate substrate to the first conductive interconnect.

13. The method of claim 12, in which forming the first conductive interconnect comprises:
forming via openings in interlayer dielectric (ILD) layers on the passive substrate to expose the insulator layer as well as a second plate portion of the first metallization layer; and
forming a first via on the insulator layer, and a second via on the second plate portion of the first metallization layer.

14. The method of claim 13, further comprising:
depositing and patterning a photoresist (PR) layer on the ILD layers on the passive substrate to expose the first via and the second via;
forming a first conductive pillar on the first via and a second conductive pillar on the second via; and
forming a first bump on the first conductive pillar and a second bump on the second conductive pillar.

15. The method of claim 14, in which forming the first bump on the first conductive pillar and the second bump on the second conductive pillar further comprises:
removing the PR layer from the ILD layers to expose the first conductive pillar on the first via and the second conductive pillar on the second via; and
reflowing the first bump on the first conductive pillar and the second bump on and the second conductive pillar.

16. The method of claim 13, further comprising:
forming a second metallization layer on the first via and on the second via;
depositing and patterning a photoresist (PR) layer on the ILD layers on the passive substrate to expose the second metallization layer;
forming a first conductive pillar on the second metallization layer on the first via and a second conductive pillar on the second metallization layer on the second via; and
forming a first bump on the first conductive pillar and a second bump on the second conductive pillar.

17. The method of claim 16, in which forming the first bump on the first conductive pillar and the second bump on the second conductive pillar further comprises:
removing the PR layer from the ILD layers to expose the first conductive pillar on the second metallization layer and the second conductive pillar on the second metallization layer; and
reflowing the first bump on the first conductive pillar and the second bump on and the second conductive pillar.

18. The method of claim 12, in which the passive substrate comprises glass.

19. The method of claim 12, in which the RF device comprises an RF inductor-capacitor (LC) filter.

20. The method of claim 19, in which the RF LC filter is incorporated in a radio frequency front-end (RFFE) module.
